(19) United States
(12) Patent Application Publication
(10) Pub. No.: US 2022/0011054 A1
(43) Pub. Date: Jan. 13, 2022

(54) HEAT CONDUCTING MEMBER

(71) Applicants: Nidec Chaun-Choung Technology Corporation, New Taipei City (TW); Nidec Corporation, Kyoto (JP)

(72) Inventors: Masaaki HANANO, Kyoto (JP); Junichi ISHIDA, Kyoto (JP); Toshihiko KOSEKI, Kyoto (JP)

(21) Appl. No.: 17/370,065

(22) Filed: Jul. 8, 2021

(30) Foreign Application Priority Data
Jul. 10, 2020 (JP) 2020-119457

(51) Int. Cl. F28D 15/04; F28D 15/02

(52) U.S. Cl. CPC F28D 15/04; H05K 7/20336; F28D 15/0233

(57) ABSTRACT

A heat conducting member includes a housing provided with a space inside, and a working medium in the space. The housing includes a first region, a second region located on one side in one direction perpendicular or substantially perpendicular to a thickness direction of the housing across the first region, and a third region located on another side in the one direction across the first region. The first region includes a first end portion connected to the second region and a second end portion connected to the third region. The first end portion is at a position in the thickness direction different from the second end portion.

### CROSS REFERENCE TO RELATED APPLICATION

The present application claims priority under 35 U.S.C. § 119 to Japanese Application JP 2020-119457, which was filed on Jul. 10, 2020, the entire contents of which are hereby incorporated herein by reference.

### 1. FIELD OF THE INVENTION

The present invention relates to a heat conducting member.

### 2. BACKGROUND

Vapor chambers as heat conducting members have been conventionally proposed. Examples of a disclosed conventional heat conducting member include a vapor chamber in a flat shape.

The vapor chamber in a flat shape may cause a housing, which is an outer frame of the vapor chamber, to be bent and deformed when external force is applied to the vapor chamber from its thickness direction. Deformation of the housing may lead to breakage of the housing.

### SUMMARY

A heat conducting member according to an example embodiment of the present disclosure includes a housing provided with a space inside, and a working medium in the space. The housing includes a first region, a second region located on one side in one direction perpendicular or substantially perpendicular to a thickness direction of the housing with respect to the first region, and a third region located on another side in the one direction with respect to the first region. The first region includes a first end portion coupled to the second region and a second end portion coupled to the third region. The first end portion has a different position from the second end portion in the thickness direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a sectional view illustrating schematic structure of a vapor chamber as a heat conducting member according to an example embodiment of the present disclosure.

FIG. 2 is a sectional view illustrating a portion of a manufacturing process of a vapor chamber according to an example embodiment of the present disclosure.

FIG. 3 is a sectional view illustrating a portion of a manufacturing process of a vapor chamber in another manufacturing method according to an example embodiment of the present disclosure.

FIG. 4 is a sectional view illustrating another structure of a vapor chamber according to an example embodiment of the present disclosure.

FIG. 5 is a sectional view illustrating yet another structure of a vapor chamber according to an example embodiment of the present disclosure.

FIG. 6 is a plan view of the vapor chamber of FIG. 1 as viewed from a thickness direction.

FIG. 7 is a plan view of another vapor chamber according to an example embodiment of the present disclosure as viewed from the thickness direction.

FIG. 8 is a perspective view illustrating yet another structure of a vapor chamber according to an example embodiment of the present disclosure.

FIG. 9 is a plan view of the vapor chamber of FIG. 8 as viewed from the thickness direction.

FIG. 10 is a sectional view illustrating yet another structure of a vapor chamber according to an example embodiment of the present disclosure.

FIG. 11 is a sectional view illustrating yet another structure of a vapor chamber according to an example embodiment of the present disclosure.

FIG. 12 is a sectional view illustrating yet another structure of a vapor chamber according to an example embodiment of the present disclosure.

FIG. 13 is a sectional view illustrating yet another structure of a vapor chamber according to an example embodiment of the present disclosure.

### DETAILED DESCRIPTION

Hereinafter, a vapor chamber 1 as a heat conducting member according to an example embodiment of the present disclosure will be described in detail with reference to the drawings. The drawings appropriately show an XYZ coordinate system as a three-dimensional orthogonal coordinate system. In the XYZ coordinate system, a Z-axis direction corresponds to a vertical direction (i.e., an up-down direction), and a +Z direction points upward (i.e., in a direction opposite to the direction of gravity), while a −Z direction points downward (i.e., in the direction of gravity). The Z-axis direction is a thickness direction of a housing 1a described later, and is also a facing direction of a lower plate 4 and an upper plate 5. The X-axis direction indicates a direction orthogonal to the Z-axis direction, and forward and reverse directions thereof are defined as a +X direction and a −X direction, respectively. The Y-axis direction indicates a direction orthogonal to both the Z-axis direction and the X-axis direction, and forward and reverse directions thereof are defined as a +Y direction and a −Y direction, respectively.

Although in the present specification, A and B being “perpendicular” to each other strictly indicate A and B intersecting at an angle of 90°, A and B intersecting at an angle within a predetermined range from 90° (e.g., an angle within a range of 90°±10°) is also included in the concept of “perpendicular” and can be treated as “perpendicular”. Although A and B being “parallel” to each other strictly indicate A and B that do not intersect, A and B intersecting at an angle of 10° or less is also included in the concept of “parallel” and can be treated as “parallel”.

In the present specification, A and B “coupling” to each other mean A and B that are mechanically “coupled” or “coupled” to each other, and do not mean A and B that are electrically coupled to each other.

In the present specification, the term, “sintering”, indicates a technique of heating powder of metal or paste containing the metal to a temperature lower than the melting point of the metal to bake particles of the metal. The term, “sintered body”, indicates an object obtained by sintering.

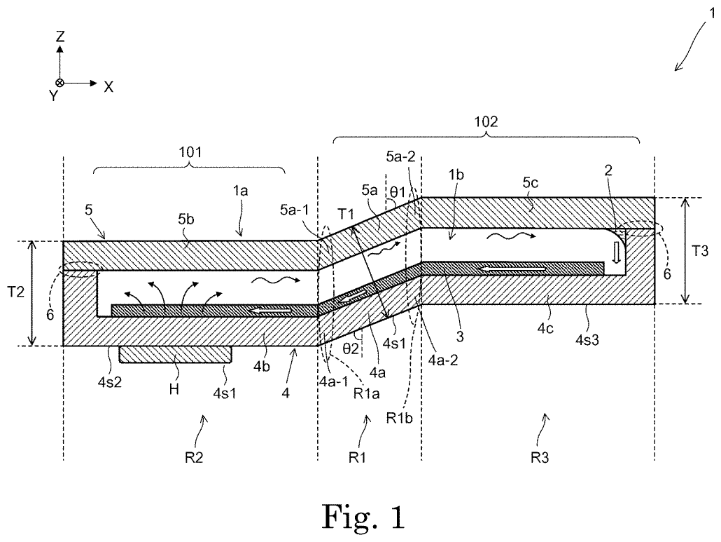

FIG. 1 is a sectional view illustrating schematic structure of a vapor chamber 1 according to an example embodiment of the present disclosure. The vapor chamber 1 is a heat conducting member that transports heat of a heating element H. As the heating element H, for example, an electronic component that generates heat or a substrate equipped with the electronic component can be considered. The heating element H is cooled by heat transport through the vapor chamber 1. The vapor chamber 1 as described above is mounted on an electronic device having a heating element H, such as a smartphone or a notebook personal computer.

The vapor chamber 1 includes a heated portion 101 and a heat dissipation portion 102. The heated portion 101 is disposed, for example, in contact with a heating element H, and is heated by heat generated by the heating element H. The heat dissipation portion 102 dissipates heat of a working medium 2 described later and heated by the heated portion 101 to the outside.

The vapor chamber 1 includes the housing 1a. The housing 1a has a part included in the heated portion 101. The other part of the housing 1a is included in the heat dissipation portion 102.

The housing 1a is provided inside with a space 1b. The space 1b is a hermetically sealed space, and is maintained in a depressurized state where pressure is lower than atmospheric pressure, for example. When the space 1b is in the depressurized state, the working medium 2 accommodated in the space 1b is likely to evaporate. The housing 1a has a thickness of 100 μm or more and 1000 μm or less, for example, in the Z-axis direction.

The working medium 2 is accommodated in the space 1b of the housing 1a. The working medium 2 is used for transporting heat. The working medium 2 is, for example, water, and may be another liquid such as alcohol.

That is, the vapor chamber 1 of the present example embodiment includes the housing 1a provided inside with the space 1b, and the working medium 2 disposed in the space 1b.

In the space 1b of the housing 1a, a wick structure 3 is disposed in addition to the working medium 2. That is, the vapor chamber 1 of the present example embodiment includes the wick structure 3. The wick structure 3 has a porous wick structure and transports the working medium 2 by capillarity. The wick structure 3 as described above is composed of, for example, a sintered body of copper. The wick structure 3 has a thickness of, for example, 100 μm or less. The wick structure 3 is located in the housing 1a over a first region R1, a second region R2, and a third region R3, which are described later.

The wick structure 3 may have any structure as long as the working medium 2 can be transported inside the housing 1a by capillarity. Thus, besides the porous wick structure (sintered wick) described above, the wick structure 3 may be a mesh wick formed of a metal mesh or a groove wick having a groove structure.

The housing 1a includes a lower plate 4. The lower plate 4 is a metal plate, e.g., a copper plate. The lower plate 4 may be formed by applying copper plating to a surface of a metal other than copper. As the metal other than copper, for example, stainless steel can be considered. The lower plate 4 is formed in a recessed shape recessed in the −Z direction.

The housing 1a further includes an upper plate 5. The upper plate 5 is located facing the lower plate 4 in the Z-axis direction. That is, the housing 1a includes the upper plate 5 and the lower plate 4 that are located facing each other in the thickness direction. The upper plate 5 is formed by bending a flat plate, for example.

The upper plate 5 is integrally provided with a strut. The strut is also called a pillar, and is in contact with the lower plate 4 to keep a distance between the lower plate 4 and the upper plate 5 constant. FIG. 1 eliminates illustration of the strut for convenience. The strut may be formed separately from the upper plate 5.

The upper plate 5 is made of the same metal material as the lower plate 4. Thus, when the lower plate 4 is made of copper, the upper plate 5 is also made of copper. When the lower plate 4 is composed of a metal plate with a stainless steel surface plated with copper, the upper plate 5 is also composed of a metal plate with a stainless steel surface plated with copper.

The housing 1a further includes a joint portion 6. The joint portion 6 has a joint structure in which the lower plate 4 and the upper plate 5 are joined to each other at outer edges thereof. That is, the joint portion 6 is located at a peripheral edge portion of the housing 1a when viewed from the Z direction. A method for joining the lower plate 4 to the upper plate 5 is not particularly limited. For example, any joining method such as hot pressing, diffusion joining, and joining using a brazing material, may be used.

Both the hot pressing and the diffusion joining are methods for joining two members by heating and pressurization, and then are distinguished from each other in the following points. The diffusion joining is performed such that atoms or particles near a joint interface between two members are diffused by heating and pressurization for several hours, for example, to join the two members to each other.

In contrast, the hot pressing is performed such that only some atoms or particles near a joint interface between two members are diffused by heating and pressurization at a lower temperature and in a shorter time than the diffusion joining, to join the two members to each other.

Due to a difference in degree of diffusion of the atoms or the particles, the joint interface itself disappears in the diffusion joining. In contrast, a portion of the joint interface disappears, and the rest is maintained as it is, in the hot pressing. Thus, the joint portion 6 formed by the diffusion bonding and the joint portion 6 formed by the hot pressing are different from each other in joint structure near the joint interface. Due to the difference in heating and pressurization time, the hot pressing has a shorter takt time for production than the diffusion joining.

The joint portion 6 may include a sealing portion. The sealing portion is, for example, a portion where an injection port for injecting the working medium 2 into the housing 1a is sealed by welding in a manufacturing process of the vapor chamber 1.

The vapor chamber 1 having the above structure causes the heated portion 101 to be heated by heat generated by the heating element H. When temperature of the heated portion 101 rises, the working medium 2 accommodated in the space 1b of the housing 1a vaporizes. Vaporized vapor moves inside the vapor chamber 1 toward the heat dissipation portion 102. The heat dissipation portion 102 cools and liquefies the vapor by heat dissipation. The working medium 2 liquefied flows inside the wick structure 3 along an inner surface of the housing 1a or by capillarity, and moves toward the heated portion 101. FIG. 1 shows a flow of vapor obtained when the working medium 2 vaporizes with black arrows, and a flow of the working medium 2 liquefied with outlined arrows. When the working medium 2 moves while being changed in state as described above, heat is continuously transported from the heated portion 101 toward the heat dissipation portion 102. As a result of transport of the heat, the heating element H in contact with the heated portion 101 is cooled.

Next, details of the upper plate 5 and the lower plate 4 will be described. The upper plate 5 includes an upper inclined portion 5a, a first upper coupling portion 5b, and a second upper coupling portion 5c. The upper inclined portion 5a is a flat plate portion inclined at a first acute angle θ1(°) with respect to the Z direction in a ZX plane. That is, the upper plate 5 includes the upper inclined portion 5a inclined with respect to a thickness direction of the housing 1a.

The first upper coupling portion 5b is coupled to the upper inclined portion 5a on one side (−X direction side) in the X direction. The second upper coupling portion 5c is coupled to the upper inclined portion 5a on the other side (+X direction side) in the X direction. That is, the upper plate 5 includes the first upper coupling portion 5b coupled to the upper inclined portion 5a, and the second upper coupling portion 5c coupled to the upper inclined portion 5a on a side opposite to the first upper coupling portion 5b.

The lower plate 4 includes the lower inclined portion 4a, the first lower coupling portion 4b, and the second lower coupling portion 4c. The lower inclined portion 4a is a flat plate portion inclined at a second acute angle θ2(°) with respect to the Z direction in the ZX plane. Although in the present example embodiment, the second acute angle θ2 has the same angle as the first acute angle θ1, it may be different from the first acute angle θ1. That is, the lower plate 4 includes the lower inclined portion 4a inclined with respect to the thickness direction of the housing 1a.

The first lower coupling portion 4b is coupled to the lower inclined portion 4a on one side (−X direction side) in the X direction. The second lower coupling portion 4c is coupled to the lower inclined portion 4a on the other side (+X direction side) in the X direction. That is, the lower plate 4 includes the first lower coupling portion 4b coupled to the lower inclined portion 4a, and the second lower coupling portion 4c coupled to the lower inclined portion 4a on a side opposite to the first lower coupling portion 4b.

The first lower coupling portion 4b has an end portion on a side in the −X direction, the end portion extending in the +Z direction and being joined to an end portion of the first upper coupling portion 5b on the side in the −X direction to form the joint portion 6. The second lower coupling portion 4c has an end portion on a side in the +X direction, the end portion extending in the +Z direction and being joined to an end portion of the second upper coupling portion 5c on the side in the +X direction to form the joint portion 6.

Next, details of the housing 1a will be described. As illustrated in FIG. 1, the housing 1a includes the first region R1, the second region R2, and the third region R3. The first region R1, the second region R2, and the third region R3 correspond to individual pieces (divided housings) when the housing 1a is divided in a cross section along the Z direction at predetermined positions in one direction (e.g., the X direction) perpendicular to the Z direction. Thus, the first region R1, the second region R2, and the third region R3 each include a portion of the upper plate 5 and the lower plate 4 that constitute the housing 1a.

In the present example embodiment, the second region R2 and the third region R3 of the housing 1a are located opposite to each other across the first region R1 in the X direction. That is, the housing 1a includes the first region R1, the second region R2 located on one side in one direction perpendicular to the thickness direction of the housing 1a across the first region R1, and the third region R3 located on the other side in the one direction across the first region R1.

The first region R1 is located substantially at the center of the housing 1a in the X direction. The first region R1 may be located by being displaced from a center position of the housing 1a in the X direction toward the side in the +X direction or the side in the −X direction. The first region R1 includes the upper inclined portion 5a of the upper plate 5 and the lower inclined portion 4a of the lower plate 4. The first region R1 includes the upper inclined portion 5a and the lower inclined portion 4a that are located facing each other across a portion of the space 1b. Thus, the first region R1 is formed in a flat plate shape as a whole.

The first region R1 includes the upper inclined portion 5a and the lower inclined portion 4a inclined with respect to the Z direction, so that the housing 1a is inclined with respect to the Z direction in the first region R1. That is, the first region R1 of the housing 1a is located by being inclined with respect to the thickness direction.

The first region R1 includes a first end portion Ria and a second end portion Rib. The first end portion Ria is connected to the second region R2. The second end portion Rib is connected to the third region R3. That is, the first region R1 includes the first end portion Ria connected to the second region R2, and the second end portion Rib connected to the third region R3.

The first end portion Ria includes a first upper end portion 5a-1 and a first lower end portion 4a-1. The first upper end portion 5a-1 is connected to the first upper coupling portion 5b located in the second region R2. The first lower end portion 4a-1 is connected to the first lower coupling portion 4b located in the second region R2.

The second end portion Rib includes a second upper end portion 5a-2 and a second lower end portion 4a-2. The second upper end portion 5a-2 is connected to the second upper coupling portion 5c located in the third region R3. The second lower end portion 4a-2 is connected to the second lower coupling portion 4c located in the third region R3.

The second region R2 is located on one side (e.g., the side in the −X direction) in the X direction across the first region R1, and is connected to the first region R1. The second region R2 includes the first upper coupling portion 5b of the upper plate 5, and the first lower coupling portion 4b of the lower plate 4. The second region R2 includes the first upper coupling portion 5b and the first lower coupling portion 4b that are located facing each other in the Z direction, i.e., in the thickness direction of the housing 1a. That is, the second region R2 includes the first upper coupling portion 5b and the first lower coupling portion 4b that are located facing each other.

The second region R2 includes the first upper coupling portion 5b and the first lower coupling portion 4b that face each other in the Z direction across the other part of the space 1b, except for the joint portion 6. Thus, the second region R2 is formed in a flat plate shape extending in the X direction as a whole.

The heating element H is disposed in contact with the first lower coupling portion 4b in the second region. Thus, the second region R2 includes the heated portion 101 heated by the heating element H.

The third region R3 is located on the other side (e.g., the side in the +X direction) in the X direction across the first region R1, and is connected to the first region R1. The third region R3 includes the second upper coupling portion 5c of the upper plate 5, and the second lower coupling portion 4c of the lower plate 4. The third region R3 includes the second upper coupling portion 5c and the second lower coupling portion 4c that are located facing each other in the Z direction, i.e., in the thickness direction of the housing 1a. That is, the third region R3 includes the second upper coupling portion 5c and the second lower coupling portion 4c that are located facing each other.

The third region R3 includes the second upper coupling portion 5c and the second lower coupling portion 4c that face each other in the Z direction across yet another part of the space 1b, except for the joint portion 6. Thus, the third region R3 is formed in a flat plate shape extending in the X direction as a whole. At least in the third region R3 of the first region R1 and the third region R3, heat of the working medium 2, transferred from the second region R2, is released to the outside. Thus, at least the third region R3 of the first region R1 and the third region R3 includes the heat dissipation portion 102 described above.

In the present example embodiment, the first region R1 of the housing 1a is located by being inclined with respect to the Z direction as described above. Thus, the second end portion Rib of the first region R1 is located by being displaced in the Z direction with respect to the first end portion Ria. That is, the first end portion Ria and the second end portion Rib are located by being displaced in the thickness direction of the housing 1a. More specifically, the second upper end portion 5a-2 of the second end portion Rib is located above (a side in the +Z direction) the first upper end portion 5a-1 of the first end portion Ria. The second lower end portion 4a-2 of the second end portion Rib is located above (the side in +Z direction) the first lower end portion 4a-1 of the first end portion Ria.

As described above, the first end portion Ria and the second end portion Rib are located by being displaced from each other in the Z direction in the first region R1, so that the housing 1a has a shape with a step formed between the second region R2 and the third region R3. That is, the housing 1a has a shape bent in the Z direction on the way from one side to the other side in the X direction. This bent shape acts as resistance against an external force from the Z direction, so that the housing 1a can be increased in strength in the Z direction. As a result, possibility that the housing 1a is deformed by an external force from the Z direction can be reduced.

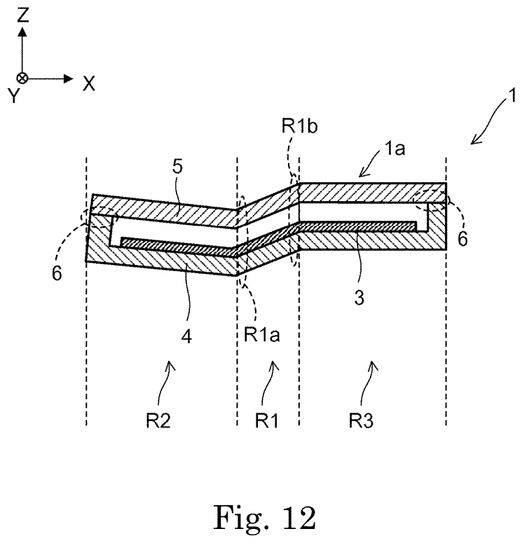

Although in the present example embodiment, the second region R2 and the third region R3 of the housing 1a are both located parallel to the X direction as illustrated in FIG. 1, any one of them may be located inclined with respect to the X direction (refer to FIG. 12). These can be summarized as follows. That is, at least one of the second region R2 and the third region R3 of the housing 1a is located along one direction perpendicular to the thickness direction of the housing 1a.

In a structure in which the first region R1 of the housing 1a is inclined with respect to the Z direction and at least one of the second region R2 and the third region R3 is located along the X direction, the housing 1a always has a region (first region R1) inclined with respect to the Z direction and a region (second region R2 or third region R3) located perpendicular to the Z direction. This enables the housing 1a to be reliably formed in a shape bent partially in the Z direction. Thus, the possibility that the housing 1a is deformed by an external force from the Z direction can be reliably reduced.

In the first region R1 of the present example embodiment, the upper inclined portion 5a and the lower inclined portion 4a are located by being inclined with respect to the Z direction and face each other across a portion of the space 1b. This enables the housing 1a to be reliably formed having a structure in which the first region R1 is inclined with respect to the Z direction.

The vapor chamber 1 includes the wick structure 3. As illustrated in FIG. 1, the wick structure 3 is located over the first region R1, the second region R2, and the third region R3 in the housing 1a.

This enables even the housing 1a having a shape bent between the second region R2 and the first region R1, and between the first region R1 and the third region R3 to allow the working medium 2 to move efficiently from the third region R3 to the second region R2 through the wick structure 3. As a result, even when the housing 1a has a bent shape, heat transport efficiency due to the movement of the working medium 2 can be improved.

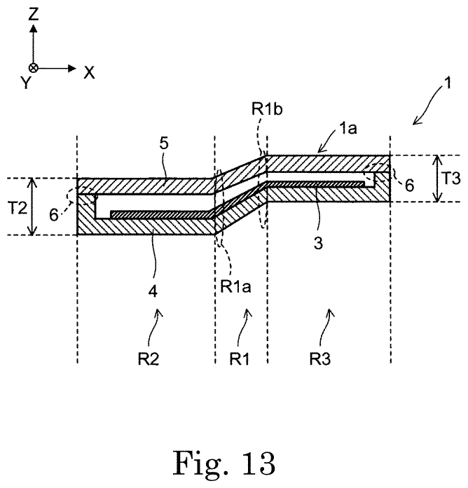

In FIG. 1, the first region R1 has a height in a normal direction of the lower inclined portion 4a, the height being indicated as T1 (μm). The second region R2 has a height in a normal direction of the first lower coupling portion 4b, the height being indicated as T2 (μm). The third region R3 has a height in a normal direction of the second lower coupling portion 4c, the height being indicated as T3 (μm). At this time, T1<T2 and T1 <T3 may be satisfied. The height T2 and the height T3 may be equal to or different from each other (refer to FIG. 13).

Here, the normal direction of the lower inclined portion 4a indicates a direction perpendicular to a bottom surface 4s1 (a surface on a side in the −Z direction) of the lower inclined portion 4a. The normal direction of the first lower coupling portion 4b indicates a direction perpendicular to a bottom surface 4s2 (a surface on the side in the −Z direction) of the first lower coupling portion 4b. The normal direction of the second lower coupling portion 4c indicates a direction perpendicular to a bottom surface 4s3 (a surface on the side in the −Z direction) of the second lower coupling portion 4c. As illustrated in FIG. 1, the structure in which the second region R2 and the third region R3 are located along the X direction allows both the normal direction of the first lower coupling portion 4b and the normal direction of the second lower coupling portion 4c to coincide with the Z direction.

That is, the height T1 of the first region R1 in the normal direction of the lower inclined portion 4a is lower than the height T2 of the second region R2 in the normal direction of the first lower coupling portion 4b and the height T3 of the third region R3 in the normal direction of the second lower coupling portion 4c.

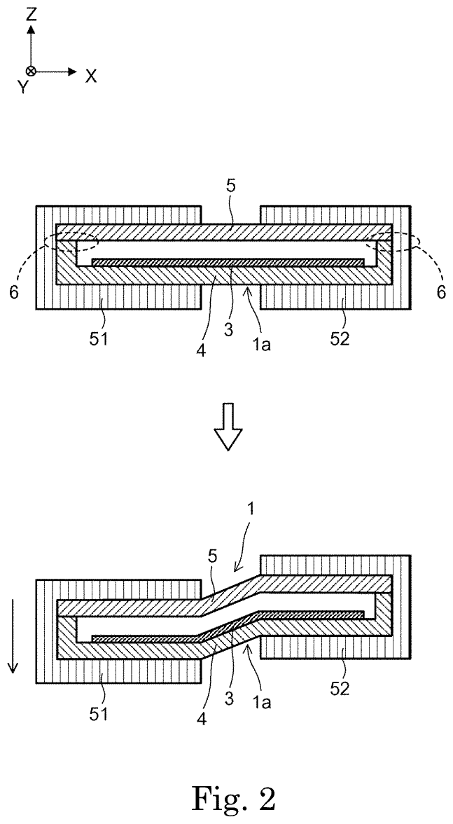

The vapor chamber 1 having such a structure can be manufactured as follows. FIG. 2 is a sectional view illustrating a portion of a manufacturing process of the vapor chamber 1 of the present example embodiment. First, the wick structure 3 is formed on the lower plate 4 having a recessed shape in the −Z direction, and then the upper plate 5 in a flat shape and the lower plate 4 are joined at the joint portion 6 to form the housing 1a in a flat shape in the X direction. Then, an end portion on the side in the −X direction of the housing 1a is pinched with a jig 51, and an end portion on the side in +X direction side thereof is pinched with a jig 52. After that, the other jig 51 is moved in the −Z direction while the jig 52 is allowed to be stationary. This enables obtaining the vapor chamber 1 having a shape in which a portion of the housing 1a is bent in the Z direction.

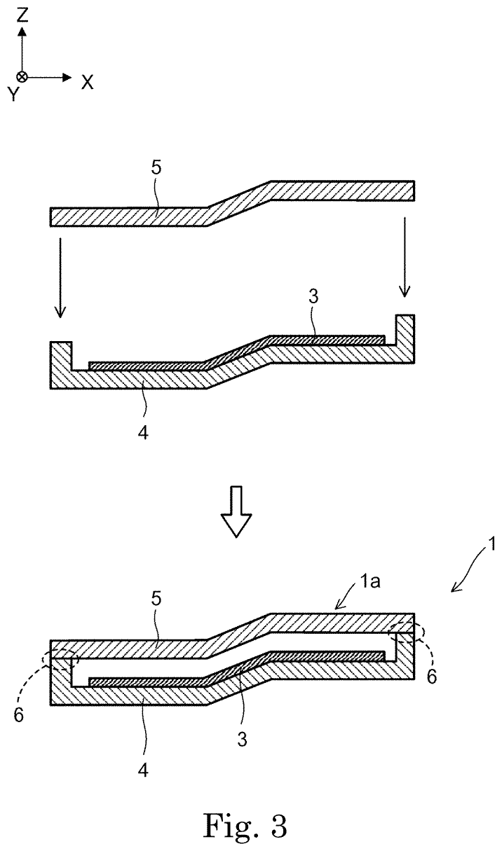

FIG. 3 is a sectional view illustrating a portion of a manufacturing process of the vapor chamber 1 in another manufacturing method. The vapor chamber 1 can also be manufactured as follows. For example, the lower plate 4 and the upper plate 5 having shapes bent in the Z direction are prepared in advance, and the wick structure 3 is formed on the lower plate 4. After that, the upper plate 5 and the lower plate 4 are joined at the joint portion 6. This enables obtaining the vapor chamber 1 having a shape in which a portion of the housing 1a is bent in the Z direction.

The housing 1a with T1<T2 and T1<T3 can be easily obtained by bending the housing 1a in a flat shape in the Z direction using the jigs 51 and 52 as illustrated in FIG. 2, or by joining the upper plate 5 and the lower plate 4 bent in the Z direction in advance as illustrated in FIG. 3. That is, the housing 1a improved in strength in the Z direction can be formed by a simple manufacturing method.

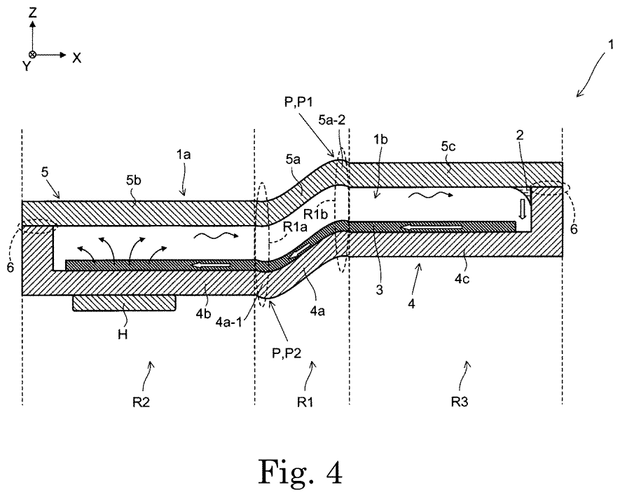

FIG. 4 is a sectional view illustrating another structure of the vapor chamber 1. As illustrated in the drawing, the upper inclined portion 5a of the housing 1a may have a first protrusion P1. The first protrusion P1 is located at the second upper end portion 5a-2 of the second end portion Rib and protrudes in the +Z direction.

The lower inclined portion 4a of the housing 1a may have a second protrusion P2. The second protrusion P2 is located at the second lower end portion 4a-1 of the first end portion Ria and protrudes in the −Z direction. The housing 1a may have the first protrusion P1 and the second protrusion P2 together, or may have only one of the first protrusion P1 and the second protrusion P2.

That is, at least one of the upper inclined portion 5a and the lower inclined portion 4a has a protrusion P protruding in the thickness direction of the housing 1a. The protrusion P indicates at least one of the first protrusion P1 and the second protrusion P2 described above.

The housing 1a having a structure with the protrusion P allows the protrusion P to act as resistance against an external force in the Z direction. This enables the housing 1a to be further improved in strength in the Z direction to reliably reduce the possibility that the housing 1a is deformed by an external force.

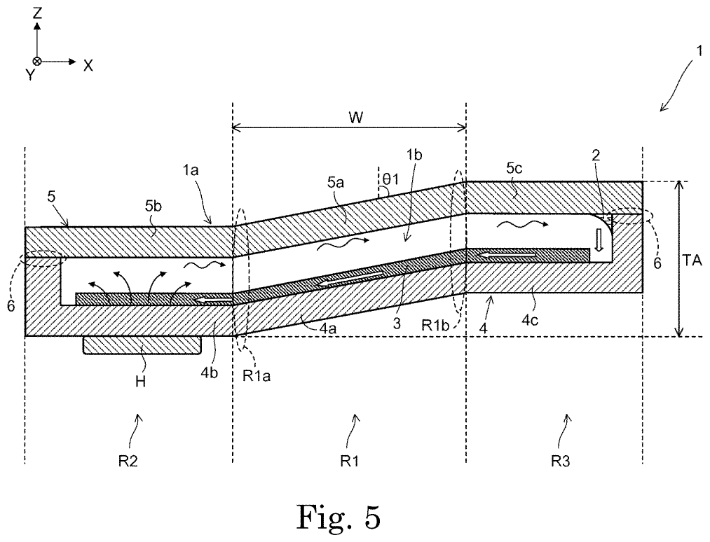

FIG. 5 is a sectional view illustrating yet another structure of the vapor chamber 1. As illustrated in the drawing, the first region R1 of the housing 1a has a width in the X direction, the width being indicated as W (μm). The housing 1a has an overall height in the Z direction, the overall height being indicated as TA (μm). At this time, W >TA may be satisfied. That is, in this case, the width W in one direction perpendicular to the thickness direction in the first region R1 of the housing is longer than the height TA in the thickness direction of the housing 1a.

When W is more than TA, the housing 1a has an inclination angle (e.g., the first acute angle θ1) with respect to the Z direction in the first region R1, the inclination angle being reliably larger than 45°. In other words, inclination of the housing 1a with respect to the XY plane in the first region R1 (particularly, inclination of the upper inclined portion 5a) is reliably gentle. This allows the working medium 2 having evaporated in the second region R2 to easily move along inclination of the inner surface of the housing 1a (particularly, the upper inclined portion 5a) in the first region R1. As a result, heat transport efficiency due to the movement of the working medium 2 in the housing 1a can be improved.

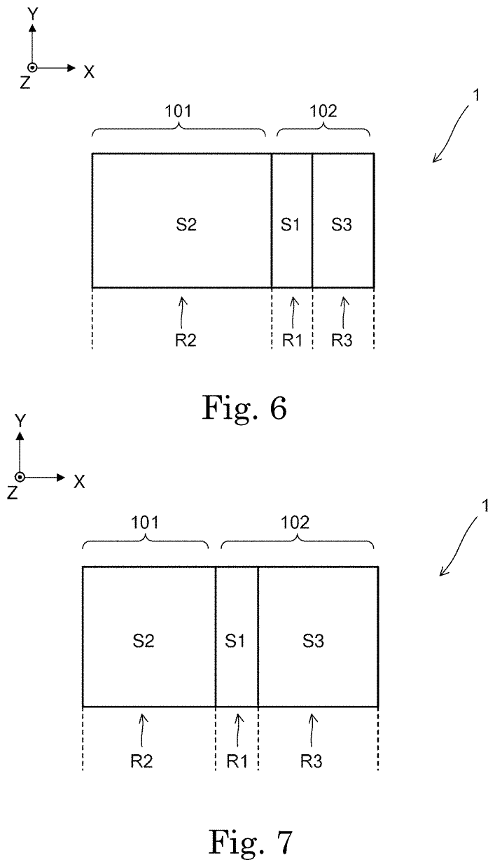

FIG. 6 is a plan view of the vapor chamber 1 of FIG. 1 as viewed from the Z direction. When the vapor chamber 1 is viewed from the Z direction, the housing 1a has an area of the first region R1, being indicated as S1 (mm²), an area of the second region R2, being indicated as S2 (mm²), and an area of the third region R3, being indicated as S3 (mm²). The area S1 is also a projected area of the first region R1 with respect to the XY plane. Similarly, the area S2 is also a projected area of the second region R2 with respect to the XY plane. The area S3 is also a projected area of the third region R3 with respect to the XY plane.

Although in the present example embodiment, S1+S3=S2 may be satisfied, S1+S3 >S2 may be satisfied as illustrated in FIG. 6. Here, it is assumed that the heating element H (refer to FIG. 1) is disposed in contact with the housing 1a in the second region R2, and the working medium 2 heated and having evaporated in the second region R2 flows toward the third region R3 through the first region R1 in the housing 1a. Thus, the second region R2 includes the heated portion 101. The first region R1 and the third region R3 include the heat dissipation portion 102.

That is, when the working medium 2 flows as gas in a flow path in the housing 1a in a direction from the second region R2 toward the third region R3 through the first region R1, the sum of the area S1 of the first region R1 and the area S3 of the third region R3 is larger than the area S2 of the second region R2 when the housing 1a is viewed from the thickness direction.

When the working medium 2 heated and having evaporated in the second region R2 sequentially flows to the first region R1 and the third region R3, the sum of the areas S1 and S3 corresponds to a heat dissipation area in the heat dissipation portion 102. The heat dissipation area (S1+S3) is larger than the area of the second region R2, so that the heat of the working medium 2 can be efficiently dissipated in the first region R1 and the third region R3.

FIG. 7 is a plan view of another vapor chamber 1 as viewed from the Z direction. As illustrated in FIG. 7, S1+S3<S2 may be satisfied. That is, when the working medium 2 flows as gas in a flow path in the housing 1a in a direction from the second region R2 toward the third region R3 through the first region R1, the sum of the area S1 of the first region R1 and the area S3 of the third region R3 is smaller than the area S2 of the second region R2 when the housing 1a is viewed from the thickness direction.

The area S2 of the second region R2 is relatively larger than the heat dissipation area (S1+S3), so that the vapor chamber 1 capable of performing heat conduction by bringing the heating element H into contact with the second region R2 can be easily formed even with the heating element H having a large size (refer to FIG. 1). That is, the vapor chamber 1 that is also applicable to cooling of the heating element H having a large size can be easily formed.

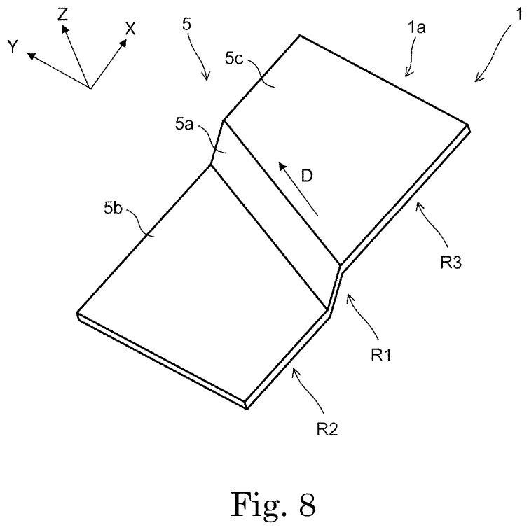

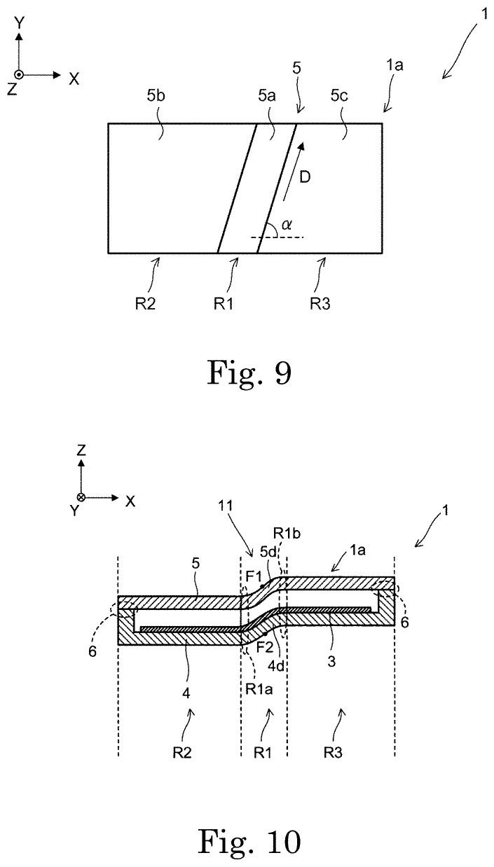

FIG. 8 is a perspective view illustrating yet another structure of the vapor chamber 1. FIG. 9 is a plan view of the vapor chamber 1 of FIG. 8 as viewed from the Z direction. The upper inclined portion 5a in the first region R1 of the housing 1a of the vapor chamber 1 may be located along a D direction intersecting the direction X at an inclination angle α (°) in the XY plane when viewed from the direction Z. At this time, the inclination angle α is an acute angle.

That is, the first region R1 of the housing 1a is located along a direction inclined with respect to one direction perpendicular to the thickness direction when viewed from the thickness direction. Here, similarly to the cases of FIGS. 6 and 7, it is assumed that the heating element H (refer to FIG. 1) is disposed in contact with the housing 1a in the second region R2, and the working medium 2 heated and having evaporated in the second region R2 flows toward the third region R3 through the first region R1 in the housing 1a.

In the structure of FIGS. 8 and 9, the working medium 2 heated and having evaporated in the second region R2 flows in the +X direction in the housing 1a and enters the first region R1. In the first region R1, the working medium 2 flows in the +X direction along the upper inclined portion 5a, i.e., along the D direction.

As described above, the working medium 2 flows in the +X direction while flowing obliquely with respect to an original flow path direction (+X direction), so that the working medium 2 can move gently in the Z direction as compared with a case where the working medium 2 flows linearly in the X direction as viewed from the Z direction. That is, the working medium 2 can flow for a longer distance in the XY plane to move in the Z direction as compared with a case of linearly flowing in the X direction as viewed from the Z direction. This enables the working medium 2 to flow reliably along near the inner surface of the housing 1a in the first region R1 to the third region R3. As a result, in the first region R1 and the third region R3, heat dissipation efficiency when heat of the working medium 2 is released to the outside through the housing 1a can be reliably improved.

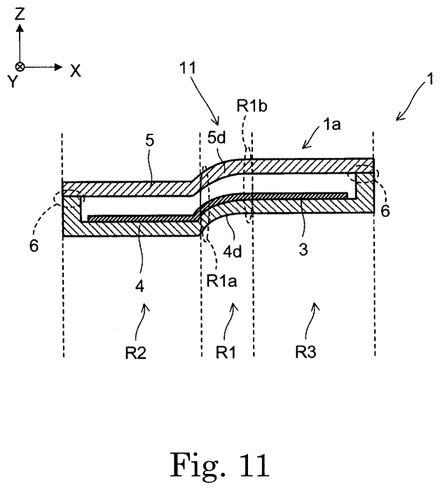

Structure of the vapor chamber 1 is not limited to the structure of the present example embodiment described above. FIGS. 10 to 13 are each a sectional view schematically illustrating yet another structure of the vapor chamber 1. As illustrated in FIGS. 10 and 11, the housing 1a of the vapor chamber 1 may include a curved portion 11 in the first region R1. The curved portion 11 is formed by, for example, replacing the upper inclined portion 5a in FIG. 1 with an upper curved portion 5d and replacing the lower inclined portion 4a with a lower curved portion 4d. In this structure, the curved portion 11 has an end portion on one side in the X direction, being the first end portion Ria, and an end portion on the other side in the X direction, being the second end portion Rib.

FIG. 10 illustrates a structure in which the curved portion 11 includes the upper curved portion 5d and the lower curved portion 4d that have surfaces curved with inflection points F1 and F2, respectively, in the ZX plane. FIG. 11 illustrates a structure in which the curved portion 11 includes the upper curved portion 5d and the lower curved portion 4d that each have a surface in a curved shape with no inflection point in the ZX plane, the curved shape protruding in the +Z direction.

As illustrated in FIG. 12, only one of the second region R2 and the third region R3 may be located along the X direction in the housing 1a. FIG. 12 illustrates an example in which only the third region R3 is located along the X direction and the second region R2 is inclined with respect to the X direction. Although not illustrated, only the second region R2 of the second region R2 and the third region R3 may be located along the X direction, and the third region R3 thereof may be located by being inclined with respect to the X direction.

As illustrated in FIG. 13, the space 1b inside the housing 1a may have a thickness in the Z direction, being different between the second region R2 and the third region R3. FIG. 13 illustrates an example in which the third region R3 has the space 1b with a thickness in the Z direction, the thickness being smaller than that in the second region R2. This structure is configured such that the lower plate 4 and the upper plate 5 are equal in thicknesses in the Z direction, and when the second region R2 has a height in the Z direction, being indicated as T2, and the third region R3 has a height in the Z direction, being indicated as T3, T2>T3 is satisfied.

Even the structure illustrated in each of FIGS. 10 to 13 enables increase in strength in the Z direction due to the first end portion Ria and the second end portion Rib being displaced in the Z direction. As a result, possibility that the housing 1a is deformed by an external force in the Z direction can be reduced.

The vapor chamber 1 of the present example embodiment described above is provided in an electronic apparatus having the heating element H by a method such as press-fitting. The term, “press-fitting”, means pressing inside by applying pressure. In particular, the vapor chamber 1 of the present example embodiment has high strength in the Z direction, so that the vapor chamber 1 is very advantageously mounted in an electronic apparatus by press-fitting in the Z direction.

The heat conducting member of the present disclosure can be used as, for example, a member for dissipating heat of a board or an electronic component mounted on an electronic apparatus.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat conducting member comprising:
a housing provided with a space inside; and
a working medium in the space; wherein
the housing includes:
a first region;
a second region located on one side in one direction perpendicular or substantially perpendicular to a thickness direction of the housing with respect to the first region; and
a third region located on another side in the one direction with respect to the first region;
the first region includes:
a first end portion connected to the second region; and
a second end portion connected to the third region;
the first end portion has a different position in the thickness direction than the second end portion.

2. The heat conducting member according to claim 1, wherein
the first region of the housing is inclined with respect to the thickness direction; and
at least one of the second region and the third region of the housing is located to extend along the one direction.

3. The heat conducting member according to claim 2, wherein
the housing includes an upper plate and a lower plate opposing each other in the thickness direction;
the upper plate includes an upper inclined portion inclined with respect to the thickness direction;
the lower plate includes a lower inclined portion inclined with respect to the thickness direction;
the first region includes the upper inclined portion and the lower inclined portion; and
the upper inclined portion and the lower inclined portion oppose each other across a portion of the space.

4. The heat conducting member according to claim 3, wherein
the upper plate includes:
a first upper coupling portion coupled to the upper inclined portion; and
a second upper coupling portion coupled to the upper inclined portion on a side opposite to the first upper coupling portion;
the lower plate includes:
a first lower coupling portion coupled to the lower inclined portion; and
a second lower coupling portion coupled to the lower inclined portion on a side opposite to the first lower coupling portion;
the second region includes the first upper coupling portion and the first lower coupling portion that oppose each other;
the third region includes the second upper coupling portion and the second lower coupling portion that oppose each other; and
the first region has a height in a normal direction of the lower inclined portion that is below a height of the second region in a normal direction of the first lower coupling portion and a height of the third region in a normal direction of the second lower coupling portion.

5. The heat conducting member according to claim 3, wherein at least one of the upper inclined portion and the lower inclined portion includes a protrusion protruding in the thickness direction of the housing.

6. The heat conducting member according to claim 1, wherein the housing has a width in the one direction in the first region that is longer than a height of the housing in the thickness direction.

7. The heat conducting member according to claim 1, wherein when the working medium flows as gas in a flow path in the housing in a direction from the second region toward the third region through the first region, a sum of an area of the first region and an area of the third region is larger than an area of the second region when the housing is viewed from the thickness direction.

8. The heat conducting member according to claim 1, wherein when the working medium flows as gas in a flow path in the housing in a direction from the second region toward the third region through the first region, a sum of an area of the first region and an area of the third region is smaller than an area of the second region when the housing is viewed from the thickness direction.

9. The heat conducting member according to claim 1, wherein the first region is located along a direction inclined with respect to the one direction when viewed from the thickness direction.

10. The heat conducting member according to claim 1, further comprising a wick structure located over the first region, the second region, and the third region in the housing.
